(19) United States
(12) Patent Application Publication
(10) Pub. No.: US 2015/0344292 A1
(43) Pub. Date: Dec. 3, 2015

(54) MICRO ELECTRO MECHANICAL SYSTEMS COMPONENT AND METHOD OF MANUFACTURING THE SAME

(71) Applicant: SAMSUNG ELECTRO-MECHANICS CO., LTD., Suwon-Si (KR)

(72) Inventors: Jung Won Lee, Suwon-Si (KR); Jong Woon Kim, Suwon-Si (KR); Seung Hun Han, Suwon-Si (KR); Min Kyu Choi, Suwon-Si (KR)

(73) Assignee: SAMSUNG ELECTRO-MECHANICS CO., LTD., Suwon-Si (KR)

(21) Appl. No.: 14/307,259

(22) Filed: Jun. 17, 2014

(30) Foreign Application Priority Data
Jun. 18, 2013 (KR) 10-2013-0069622

(51) Int. Cl. B81B 3/00; B81C 1/00

(52) U.S. Cl. CPC B81B 3/0021; B81C 1/00158; B81B 2201/0235; B81B 2201/025; B81B 2203/0127; B81C 2201/013

(57) ABSTRACT

Disclosed herein is a MEMS component including: a membrane; a mass body connected to the membrane; and a support connected to the membrane and supporting the mass body in a floated state to be displaced, wherein the membrane has an upper electrode and an upper piezoelectric material disposed on one side thereof and has a lower electrode and a lower piezoelectric material disposed on the other side thereof, based on an insulating adhesive layer.

### CROSS REFERENCE TO RELATED APPLICATION

This application claims the benefit of Korean Patent Application No. 10-2013-0069622, filed on Jun. 18, 2013, entitled “Micro Electro Mechanical Systems Component And Manufacturing Method Of The Same” which is hereby incorporated by reference in its entirety into this application.

### BACKGROUND OF THE INVENTION

1. Technical Field

The present invention relates to a micro electro mechanical systems (MEMS) component and a method of manufacturing the same.

2. Description of the Related Art

A micro electro mechanical systems (MEMS) is a technology of manufacturing an ultra micro mechanical structure, such as a very large scale integrated circuit, an inertial sensor, a pressure sensor, and an oscillator, by processing silicon, crystal, glass, or the like. A MEMS component have precision of a micrometer ( 1/1,000,000 meter) or less and may be structurally mass-produced as a micro product at low cost by applying a semiconductor micro process technology of repeating processes, such as a deposition process and an etching process.

Among the MEMS components, an inertial sensor has been used in various applications, for example, military applications, such as an artificial satellite, a missile, an unmanned aircraft, vehicle applications, such as an air bag, an electronic stability control (ESC) and a black box for a vehicle, hand shaking prevention applications of a camcorder, motion sensing applications of a mobile phone or a game machine, a navigation application, and the like.

The inertial sensor generally adopts a configuration in which a mass body is adhered to an elastic substrate, such as a membrane, in order to measure acceleration and angular velocity. Through the above-mentioned configuration, the inertial sensor may calculate the acceleration by measuring inertial force applied to the mass body and may calculate the angular velocity by measuring Coriolis force applied to the mass body.

In detail, a scheme of measuring the acceleration and the angular velocity using the inertial sensor is as follows. First, the acceleration may be calculated by Newton's law of motion “F=ma”, when “F” represents inertial force applied to the mass body, “m” represents a mass of the mass body, and “a” is acceleration to be measured. Among others, the acceleration a may be obtained by sensing the inertial force F applied to the mass body and dividing the sensed inertial force F by the mass m of the mass body that is a predetermined value. Further, the angular velocity may be obtained by Coriolis force “F=2 mΩ×v”, where “F” represents the Coriolis force applied to the mass body, “m” represents the mass of the mass body, “Ω” represents the angular velocity to be measured, and “v” represents the motion velocity of the mass body. Among others, since the motion velocity V of the mass body and the mass m of the mass body are values known in advance, the angular velocity Ω may be obtained by detecting the Coriolis force (F) applied to the mass body.

Meanwhile, the inertial sensor among the MEMS components according to the prior art includes a piezoelectric material disposed on an upper portion of a membrane (diaphragm) in order to drive a mass body or sense displacement of the mass body, as disclosed in the following Prior Art Document. However, since the piezoelectric material disposed on the upper portion of the membrane is formed of a single layer, a force for driving the mass body may be relatively weakened when voltage is applied thereto. Further, when the displacement of the mass body is sensed, relatively low charges are output and therefore the sensitivity of the inertial sensor may be degraded.

### PRIOR ART DOCUMENT

### Patent Document

(Patent Document 1) U.S. Pat. No. 5,488,862

### SUMMARY OF THE INVENTION

The present invention has been made in an effort to provide a MEMS component capable of providing double sensitivity and double driving displacement by forming a piezoelectric material in two layers, and a method of manufacturing the same.

Further, the present invention has been made in an effort to provide a small, light MEMS component capable of driving a mass body even when a relatively low voltage is applied thereto and outputting relatively high charges when a displacement of a mass body is sensed, by forming a piezoelectric material in two layers, and a method of manufacturing the same.

In addition, the present invention has been made in an effort to provide to a MEMS component with improved sensitivity by disposing a piezoelectric material on an upper end and a lower end of a membrane, and a method of manufacturing the same.

According to a preferred embodiment of the present invention, there is provided a MEMS component, including: a membrane; a mass body connected to the membrane; and a support connected to the membrane and supporting the mass body in a floated state to be displaced, wherein the membrane has an upper electrode, an upper piezoelectric material, a lower electrode, a lower piezoelectric material and insulating adhesive layer and, the upper electrode and the upper piezoelectric material are disposed on one side of the insulating adhesive layer and the lower electrode and the lower piezoelectric material are disposed on the other side of the insulating adhesive layer.

The membrane may include: with respect to a stacked direction in which the membrane is coupled with the mass body, a lower piezoelectric material adjacent to the mass body; a lower electrode connected to the lower piezoelectric material; an insulating adhesive layer disposed on the lower piezoelectric material and the lower electrode; an upper piezoelectric material disposed on the insulating adhesive layer; and an upper electrode connected to the upper piezoelectric material.

The lower electrode and the upper electrode may be exposed to the outside of the membrane.

The membrane may further include an insulating layer coupled with the mass body and the support.

The upper electrode may be formed by forming a via that is formed on the upper piezoelectric material and filling and patterning the via.

The lower electrode may be formed by forming a via that is formed on the lower piezoelectric material and filling and patterning the via.

According to another preferred embodiment of the present invention, there is provided a method of manufacturing a MEMS component, including: (A) preparing a first wafer and a second wafer and forming a first piezoelectric material and a first electrode on the first wafer and a second piezoelectric material and a second electrode on the second wafer; (B) bonding the first wafer and the second wafer to allow the first and second piezoelectric materials and the first and second electrodes to face each other; and (C) removing the first wafer or the second wafer and opening the first electrode and the second electrode.

In the (A), the first electrode may be formed by depositing a lower electrode on the first wafer, depositing a first piezoelectric material on the lower electrode, and forming the via in the first piezoelectric material and then performing the deposition of the upper electrode.

In the (A), the second electrode may be formed by depositing a lower electrode on the second wafer, depositing a second piezoelectric material on the lower electrode, and forming the via in the second piezoelectric material and then performing the deposition of the upper electrode.

In the (A), the first wafer and the second wafer may be formed of a Si wafer.

In the (B), the first wafer and the second wafer are coupled to each other by using an insulating binder and the first electrode of the first wafer and the second electrode of the second wafer are coupled to each other to be disposed on both sides with respect to the insulating binder.

The method of manufacturing a MEMS component may further include: after the (C), (D) forming a support part and a mass body by etching the first wafer or the second wafer which is remained

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view schematically illustrating a MEMS component according to a preferred embodiment of the present invention; and

FIGS. 2A to 2E are process diagrams schematically illustrating a method of manufacturing the MEMS component illustrated in FIG. 1.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

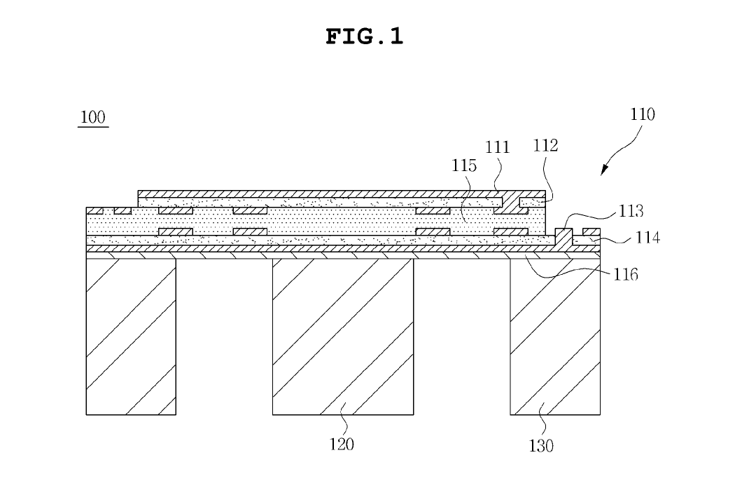

FIG. 1 is a cross-sectional view schematically illustrating a MEMS component according to a preferred embodiment of the present invention. As illustrated, the MEMS component 100 includes a membrane 110, a mass body 120, and a support part 130.

Further, the membrane 110 is formed in a plate shape and is configured of a flexible substrate which has elasticity to allow the mass body 120 to be displaced.

Further, the mass body 120 is coupled with one surface of the membrane 110 and is displaced by inertial force, external force, Coriolis force, driving force, and the like.

Further, the support part 130 is coupled with one surface of the membrane and supports the mass body 120 in a floated state to be able to be displaced.

In this case, the mass body 120 is disposed at a central portion of the membrane 110 and the support part 130 is formed in a hollow shape to allow the mass body 120 in a hollow part to be displaced. Further, the support part 130 is disposed at an edge portion of the membrane 110, and thus secures a space to allow the mass body 120 to be displaced.

Further, the mass body 120 may be formed in a cylindrical shape and the support part 130 may be formed in a cylindrical shape or a square pillar shape. Further, the shape of the mass body 120 and the support part 130 is not limited thereto, and therefore may be formed in any shape known in the art.

Meanwhile, the membrane 110, the mass body 120, and the support part 130 which are described above may be formed by selectively etching a Si wafer on which a micro electro mechanical systems (MEMS) process is easily performed.

Therefore, an insulating layer 116 may be disposed between the mass body 120 and the membrane 110 and between the support part 130 and the membrane 110. However, the membrane 110, the mass body 120, and the support part 130 are not necessarily formed by etching the Si substrate, but may also be formed by etching a general glass substrate, or the like.

Hereinafter, technical configuration, shapes, organic coupling and action effects in the MEMS component according to the preferred embodiment of the present invention will be described in more detail.

The membrane 110 is configured of an upper electrode 111, an upper piezoelectric material 112, a lower electrode 113, a lower piezoelectric material 114, an insulating adhesive layer 115, and an insulating layer 116.

Further, according to the laminated order, the lower end of the membrane 110 coupled with the mass body 120 is provided with the insulating layer 116, the upper portion of the insulating layer 116 is provided with the lower electrode 113 and the lower piezoelectric material 114, the upper portion of the lower electrode 113 is provided with the insulating adhesive layer 115, and the upper portion of the insulating adhesive layer 115 is provided with the upper electrode 111 and the upper piezoelectric material 112 to allow the upper electrode 111 to be exposed to the outside.

According to the configuration as described above, the membrane 110 is simultaneously provided with the upper piezoelectric material 112 and the lower piezoelectric material 114, and thus is configured of a dual structure which is two layers, such that double charge may be output.

In more detail, the upper piezoelectric material 112 and the lower piezoelectric material 114 are each connected to the upper electrode 111 and the lower electrode 113 to drive the mass body 120 or sense the displacement of the mass body 120.

Further, the upper piezoelectric material 112 and the lower piezoelectric material 114 may be made of lead zirconate titanate (PZT), barium titanate (BaTiO₃), lead titanate (PbTiO₃), lithium niobate (LiNbO₃), quartz, and the like.

Further, as described above, the upper electrode 111 is electrically connected to the upper piezoelectric material 112 and is formed to be exposed on the membrane 110. This is to electrically connect to the outside by wire bonding, and the like.

Further, the lower electrode 113 is electrically connected to the lower piezoelectric material 114 and is formed to be exposed outside the membrane 110. Similar to the upper electrode, this is to electrically connect to the outside by the wire bonding, and the like.

When voltage is applied to the upper piezoelectric material 112 and the lower piezoelectric material 114, respectively, through the upper electrode 111 and the lower electrode 113, an inverse piezoelectric effect which expands and contracts the upper piezoelectric material 112 and the lower piezoelectric material 114 is generated and the mass body 120 disposed on a lower portion of the membrane 110 may be driven by using the inverse piezoelectric effect.

To the contrary, when a stress is applied to the upper piezoelectric material 112 and the lower piezoelectric material 114, a piezoelectric effect generating charges to the upper electrode 111 and the lower electrode 113 each connected thereto is generated and the displacement of the mass body 120 disposed on the lower portion of the membrane 110 may be sensed by using the piezoelectric effect.

Further, as illustrated in FIG. 1, the upper piezoelectric material 112 is provided with a via and the upper electrode 111 may be filled in the via, exposed on an upper portion of the membrane, and patterned.

Further, the upper piezoelectric material 112 is formed on the upper portion of the membrane 110 and the lower piezoelectric material 114 is formed on the lower portion of the membrane 110 based on the stacked direction. When the membrane 110 is displaced, this is to consider that the upper and lower portions of the membrane are the most stressed.

To this end, the upper piezoelectric material 112 and the lower piezoelectric material 114 are provided with vias and the upper electrode is disposed on the upper portion of the membrane and the lower electrode is disposed on the lower portion of the membrane through the vias.

Further, as described above, in the MEMS component 100 according to the preferred embodiment of the present invention, the insulating layer 116 may be removed.

According to the above-mentioned configuration, the MEMS component according to the preferred embodiment of the present invention includes the upper piezoelectric material 112 and the lower piezoelectric material 114 each disposed on the upper and lower portions of the membrane 110 to simultaneously obtain the piezoelectric output on the upper and lower surfaces thereof, such that the MEMS component may double the sensor sensitivity and the driving displacement and may be implemented as a small, light type.

Hereinafter, a method of manufacturing a MEMS device according to the preferred embodiment of the present invention will be described in more detail.

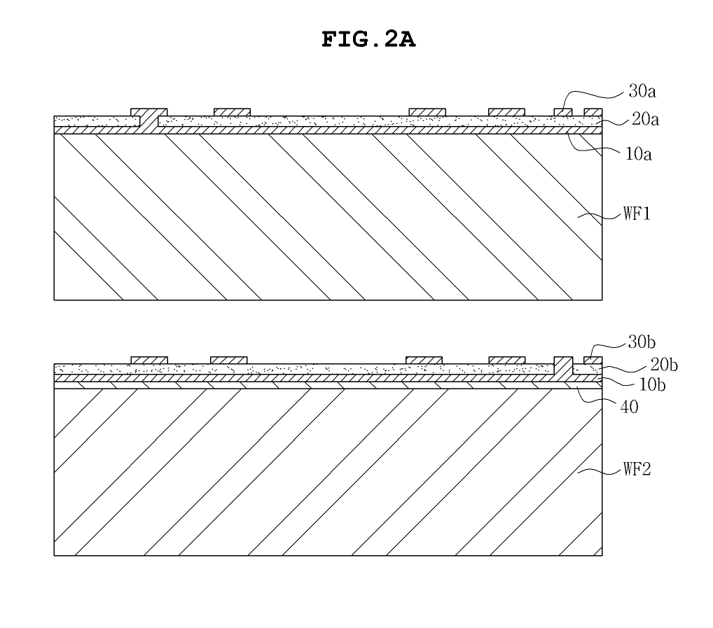

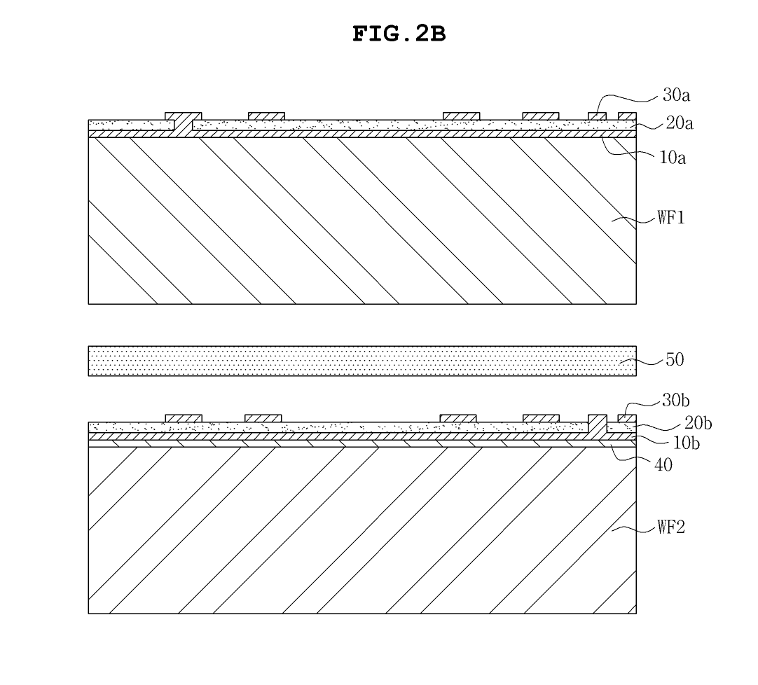

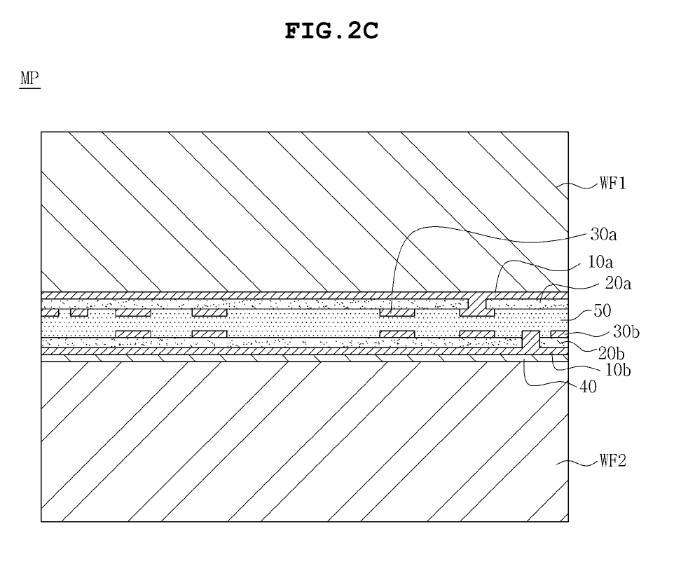

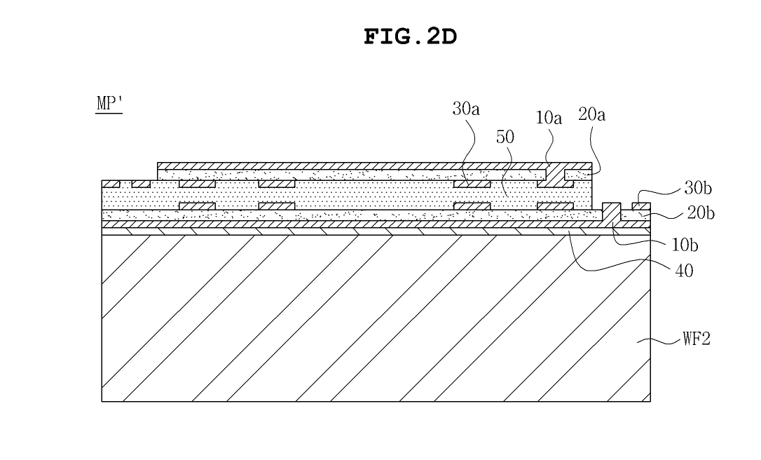

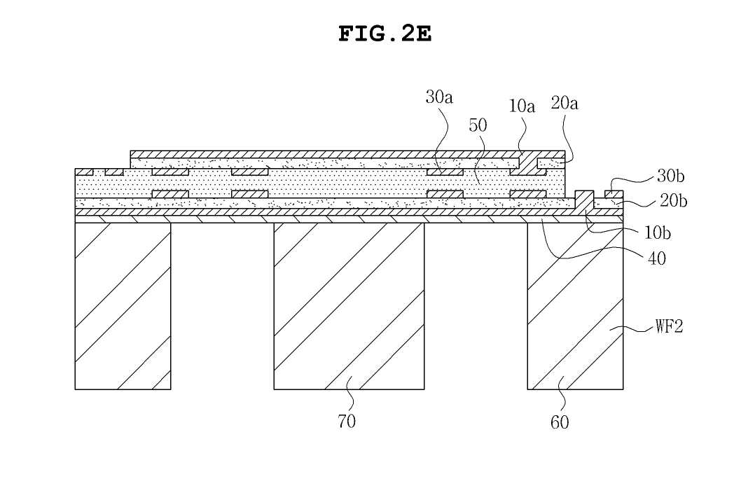

FIG. 2A illustrates a process of forming a piezoelectric material and an electrode. In more detail, a first wafer WF1 and a second wafer WF2 are prepared. Further, a first piezoelectric material 20a and first electrodes 10a and 30a are deposited on the first wafer WF1 and a second piezoelectric material 20b and second electrodes 10b and 30b are deposited on the second wafer WF2.

Further, only the second piezoelectric material 20b and the second electrodes 10b and 30b may be deposited without including an electrically insulating layer 40.

Further, the first electrodes 10a and 30a are configured to include the first lower electrode 10a and the first upper electrode 30a. To this end, the first lower electrode 10a is first deposited on the first wafer WF1, the first piezoelectric material 20a is deposited on the lower electrode 10a, and then the deposition of the first upper electrode 30a is performed by forming the via in the piezoelectric material 20a and then performing filling and patterning thereon.

Further, the second electrodes 10b and 30b are configured to include the second lower electrode 10b and the second upper electrode 30b. To this end, the lower electrode 10b is deposited on the second wafer WF2 similar to the first wafer WF1, the second piezoelectric material 20b is deposited on the lower electrode 10b, and the deposition of the second upper electrode 30b is performed by forming the via in the piezoelectric material 20a and then performing filling and patterning thereon.

Further, the first wafer WF1 and the second wafer WF2 may be formed of a Si wafer or a glass wafer instead of a SOI wafer, which may save production costs.

Next, FIGS. 2B and 2C illustrating a bonding process of the first wafer WF1 and the second wafer WF2.

In more detail, as illustrated in FIG. 2A, the first wafer WF1 on which the first piezoelectric material 20a and the first electrodes 10a and 30a are formed and the second wafer WF2 on which the second piezoelectric material 20b and the second electrodes 10b and 30b are formed are bonded by using an insulating binder 50.

In this case, the first piezoelectric material 20a and the first electrodes 10a and 30a on the first wafer WF1 and the second piezoelectric material 20b and the second electrodes 10b and 30b on the second wafer WF2 are disposed to face each other based on the insulating binder 50 and the second wafer WF2, the second piezoelectric material 20b and the second electrodes 10b and 30b, the insulating binder 50, the first piezoelectric material 20a and the first electrodes 10a and 30a, and the first wafer WF1 are coupled with each other to be stacked in order.

Therefore, the wafers are disposed at both sides based on the dual electrode and the piezoelectric material to form a multi-layer piezoelectric structure (MP).

FIG. 2D illustrates an etching process and an electrode opening process.

In more detail, in the multi-layer piezoelectric structure (MP) illustrated in FIG. 2C, the electrode is opened by removing the wafer on one side thereof.

That is, in the multi-layer piezoelectric substrate structure (MP), the first upper electrode 30a is opened by removing the first wafer WF1. Further, the second upper electrode 30b is opened by removing the second piezoelectric material 20b, the first lower electrode 10a, and the insulating binder 50, thereby forming a multi-layer piezoelectric structure (MP′).

Therefore, the multi-layer piezoelectric structure (MP) may be electrically connected to the outside by the wire bonding, and the like, by opening the first electrodes 10a and 30a connected to the first piezoelectric material 20a and the second electrodes 10b and 30b connected to the second piezoelectric material 20b to the outside, respectively.

Further, FIG. 2E illustrates a process of forming the mass body and the support.

In more detail, in the multi-layer piezoelectric structure (MP′) illustrated in FIG. 2D, the support and the mass body are formed by etching the wafer on one side thereof which is not removed. FIG. 2E illustrates an exemplary embodiment of etching the second wafer WF2 to form the support 60 and the mass body 70.

According to the manufacturing method illustrated in FIGS. 2A to 2E as described above, the MEMS component having the dual piezoelectric material illustrated in FIG. 1 may be obtained, and the MEMS component having the dual piezoelectric material may be implemented by forming the first piezoelectric material 20a as the upper piezoelectric material and forming the second piezoelectric material 20b as the lower piezoelectric material and forming the first electrodes 10a and 30a as the electrode of the upper piezoelectric material and forming the second electrodes 10b and 30b as the electrode of the lower piezoelectric material.

As set forth above, according to the preferred embodiments of the present invention, it is possible to obtain the small, light MEMS component capable of providing the double sensitivity and the double driving displacement, driving the mass body even when the relatively low voltage is applied thereto, and outputting relatively high charges when the displacement of the mass body is sensed, by forming the piezoelectric material in two layers and the MEMS component with improved sensitivity by disposing the piezoelectric material on the upper end and the lower end of the membrane, and the method of manufacturing the same.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A MEMS component, comprising:
a membrane;
a mass body connected to the membrane; and
a support connected to the membrane and supporting the mass body in a floated state to be displaced,
wherein the membrane has an upper electrode, an upper piezoelectric material, a lower electrode, a lower piezoelectric material and insulating adhesive layer and, the upper electrode and the upper piezoelectric material are disposed on one side of the insulating adhesive layer and the lower electrode and the lower piezoelectric material are disposed on the other side of the insulating adhesive layer.

2. The MEMS component as set forth in claim 1, wherein the membrane includes; with respect to a stacked direction in which the membrane is coupled with the mass body,
a lower piezoelectric material adjacent to the mass body;
a lower electrode connected to the lower piezoelectric material;
an insulating adhesive layer disposed on the lower piezoelectric material and the lower electrode;
an upper piezoelectric material disposed on the insulating adhesive layer; and
an upper electrode connected to the upper piezoelectric material.

3. The MEMS component as set forth in claim 2, wherein the lower electrode and the upper electrode are exposed to the outside of the membrane.

4. The MEMS component as set forth in claim 2, wherein the membrane further includes an insulating layer coupled with the mass body and the support.

5. The MEMS component as set forth in claim 2, wherein the upper electrode is filled and patterned on a via that is formed on the upper piezoelectric material.

6. The MEME component as set forth in claim 2, wherein the lower electrode is filled and patterned on the via that is formed on the lower piezoelectric material

7. A method of manufacturing a MEMS component, comprising:
(A) preparing a first wafer and a second wafer and forming a first piezoelectric material and a first electrode on the first wafer and a second piezoelectric material and a second electrode on the second wafer;
(B) bonding the first wafer and the second wafer to allow the first and second piezoelectric materials and the first and second electrodes to face each other; and
(C) removing the first wafer or the second wafer, etching the first electrode and opening the first electrode and the second electrode.

8. The method as set forth in claim 7, wherein in the (A), the first electrode is formed by depositing a lower electrode on the first wafer, depositing a first piezoelectric material on the lower electrode, and forming the via in the first piezoelectric material and then performing the deposition of the upper electrode.

9. The method as set forth in claim 7, wherein in the (A), the second electrode is formed by depositing a lower electrode on the second wafer, depositing a second piezoelectric material on the lower electrode, and forming the via in the second piezoelectric material and then performing the deposition of the upper electrode.

10. The method as set forth in claim 7, wherein in the (A), the first wafer and the second wafer are formed of a Si wafer.

11. The method as set forth in claim 7, wherein in the (B), the first wafer and the second wafer are coupled to each other by using an insulating binder and the first electrode of the first wafer and the second electrode of the second wafer are coupled to each other to be disposed on both sides with respect to the insulating binder.

12. The method as set forth in claim 7, further comprising: after the (C),
(D) forming a support part and a mass body by etching the first wafer or the second wafer which is remained.
